(19) United States
(12) Patent Application Publication
(10) Pub. No.: US 2025/0336832 A1
(43) Pub. Date: Oct. 30, 2025

(54) SEMICONDUCTOR PACKAGE AND METHOD FOR MANUFACTURING THE SAME

(71) Applicant: SAMSUNG ELECTRONICS CO., LTD., Suwon-si (KR)

(72) Inventor: Junghoon KANG, Suwon-si (KR)

(73) Assignee: SAMSUNG ELECTRONICS CO., LTD., Suwon-si (KR)

(21) Appl. No.: 18/934,372

(22) Filed: Nov. 1, 2024

(30) Foreign Application Priority Data
Apr. 29, 2024 (KR) 10-2024-0057025

(51) Int. Cl. H01L 23/538; H01L 21/48; H01L 23/15

(52) U.S. Cl. CPC H01L 23/5383; H01L 21/4857; H01L 23/5386; H01L 23/15

(57) ABSTRACT

A semiconductor package includes a core portion including glass, a vertical connection terminal penetrating the core portion, an upper buildup portion at least partially covering an upper surface of the core portion, and a lower buildup portion at least partially covering a lower surface of the core portion, where the upper buildup portion includes a first insulating pattern at least partially covering the upper surface of the core portion and an upper surfaces of the vertical connection terminal and a first wiring pattern penetrating the first insulating pattern and connected to the vertical connection terminal, where the lower buildup portion includes a second insulating pattern at least partially covering the lower surface of the core portion and a lower surface of the vertical connection terminal, and a second wiring pattern penetrating the second insulating pattern and connected to the vertical connection terminals.

### CROSS-REFERENCE TO RELATED APPLICATIONS

This application is based on and claims priority to Korean Patent Application No. 10-2024-0057025, filed on Apr. 29, 2024, in the Korean Intellectual Property Office, the disclosure of which is incorporated by reference herein in its entirety.

### BACKGROUND

Example embodiments of the disclosure relate to a semiconductor package and a method for manufacturing the same.

With development of the electronics industry, demands for higher functionality, higher speed, and miniaturization of an electronic component are increasing. In response to this trend, recent packaging technology is progressing in a direction in which a plurality of semiconductor chips are mounted within one package.

A semiconductor package may refer to an integrated circuit chip implemented in a form suitable for implementation in an electronic product. In general, the semiconductor package may be manufactured in a method in which the semiconductor chip is mounted on a printed circuit board (PCB), and the semiconductor chip and the PCB are electrically connected by using a bonding wire or a bump. Semiconductor package are developing with goals of miniaturization, weight reduction, and reduction of a manufacturing cost. In addition, as application fields of the semiconductor chip expand to a large-capacity storage device, various types of the semiconductor package are appearing. In particular, as an integration level of the semiconductor chip or the semiconductor package increases, various electrical characteristics and structural characteristics may be required for a package substrate on which the semiconductor chip or the semiconductor package is mounted.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package with improved structural stability and a method for manufacturing the same.

One or more example embodiments provide a method of manufacturing a semiconductor package with less defects, and a semiconductor package manufactured therethrough.

Additional aspects will be set forth in part in the description which follows and, in part, will be apparent from the description, or may be learned by practice of the presented embodiments.

According to an aspect of an example embodiment, a semiconductor package may include a core portion including glass, a vertical connection terminal penetrating the core portion, an upper buildup portion at least partially covering an upper surface of the core portion, and a lower buildup portion at least partially covering a lower surface of the core portion, where the upper buildup portion includes a first insulating pattern at least partially covering the upper surface of the core portion and an upper surface of the vertical connection terminal and a first wiring pattern penetrating the first insulating pattern and connected to the vertical connection terminal, where the lower buildup portion includes a second insulating pattern at least partially covering the lower surface of the core portion and a lower surface of the vertical connection terminal, and a second wiring pattern penetrating the second insulating pattern and connected to the vertical connection terminal, and where a surface roughness of the upper surface of the core portion and a surface roughness of the lower surface of the core portion are respectively larger than a surface roughness of an upper surface of the first insulating pattern and a surface roughness of a lower surface of the second insulating pattern.

According to an aspect of an example embodiment, a semiconductor package may include a package substrate, and a semiconductor chip on the package substrate, where the package substrate includes a core portion including glass, an upper buildup portion at least partially covering an upper surface of the core portion, and a lower buildup portion at least partially covering a lower surface of the core portion, where the upper buildup portion includes a first upper insulating pattern contacting the upper surface the core portion and an upper wiring pattern on the first upper insulating pattern, where the lower buildup portion includes a first lower insulating pattern contacting the lower surface of the core portion and a lower wiring pattern on the first lower insulating pattern, where the first upper insulating pattern and the first lower insulating pattern include pillars therein, the core portion includes recesses on the upper surface and the lower surface of the core portion and widths and depths of the recesses are smaller than diameters of the pillars.

According to an aspect of an example embodiment, a method of manufacturing a semiconductor package may include providing a core portion including glass, forming a first hole extending from a first surface toward the inside of the core portion by performing a first etching process on the first surface of the core portion, forming a via hole by forming a second hole extending from a second surface toward the inside of the core portion by performing a second etching process on the second surface of the core portion, the second surface of the core portion being opposite to the first surface of the core portion and the second hole being connected to the first hole, forming a vertical connection terminal by filling the via hole with a conductive material, forming a first insulating pattern contacting the first surface of the core portion, forming a first wiring pattern penetrating the first insulating pattern and connected to the vertical connection terminal, forming a second insulating pattern contacting the second surface of the core portion, and forming a second wiring pattern penetrating the second insulating pattern and connected to the vertical connection terminal, where during the first etching process, the first surface of the core portion is etched together to increase a surface roughness of the first surface, during the second etching process, the second surface of the core portion is etched together to increase a surface roughness of the second surface, and the first insulating pattern and the second insulating pattern include pillars therein.

According to an aspect of an example embodiment, a method of manufacturing a semiconductor package may include providing a core portion including glass, forming a vertical connection terminal to penetrate the core portion, forming an upper buildup portion to at least partially cover an upper surface of the core portion, and forming a lower buildup portion to at least partial cover a lower surface of the core portion, wherein the upper buildup portion includes a first insulating pattern at least partially covering the upper surface of the core portion and an upper surface of the vertical connection terminal, and a first wiring pattern penetrating the first insulating pattern and connected to the vertical connection terminal, wherein the lower buildup portion includes a second insulating pattern at least partially covering the lower surface of the core portion and a lower surface of the vertical connection terminal, and a second wiring pattern penetrating the second insulating pattern and connected to the vertical connection terminal, and where a surface roughness of the upper surface of the core portion and a surface roughness of the lower surface of the core portion are respectively larger than a surface roughness of an upper surface of the first insulating pattern and a surface roughness of a lower surface of the second insulating pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more embodiments;

FIGS. 2 to 4 are enlarged diagrams illustrating examples of region A of FIG. 1 according to one or more embodiments;

FIG. 5 is a cross-sectional view illustrating a semiconductor package according to one or more embodiments;

FIG. 6 is an enlarged diagram illustrating region B of FIG. 5 according to one or more embodiments;

FIG. 7 is a cross-sectional view illustrating a semiconductor package according to one or more embodiments;

FIG. 8 is an enlarged diagram illustrating region C of FIG. 7 according to one or more embodiments;

FIG. 9 is a cross-sectional view illustrating a semiconductor package according to one or more embodiments;

FIGS. 10 and 11 are enlarged diagrams illustrating examples of region D of FIG. 9 according to one or more embodiments;

FIGS. 12 and 13 are cross-sectional views illustrating a semiconductor package according to one or more embodiments;

FIGS. 14A to 20A are cross-sectional views illustrating a method for manufacturing a semiconductor package according to one or more embodiments; and

FIGS. 14B to 20B are enlarged diagrams respectively illustrating region E of FIGS. 14A to 20A according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being

“over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, terms such as “cover,” “surround,” etc., may indicate a partial or full covering/surrounding.

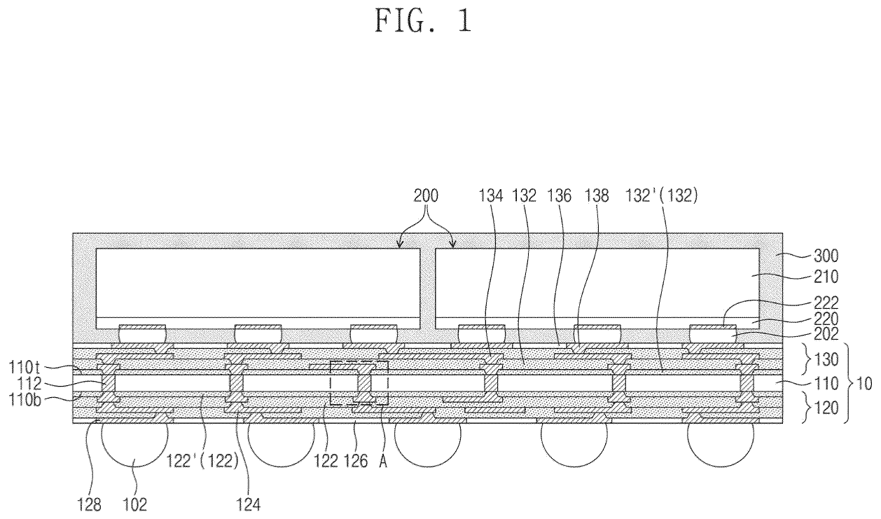

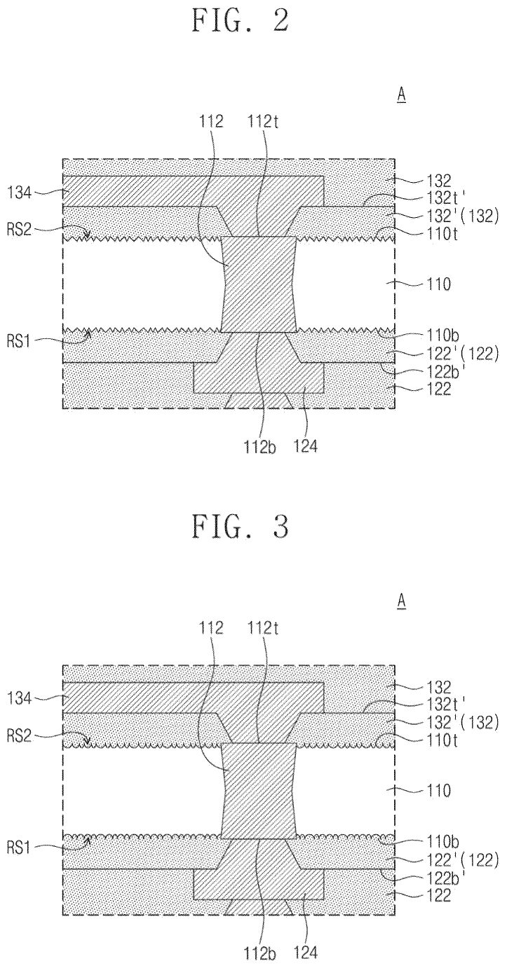

FIG. 1 is a cross-sectional view illustrating a semiconductor package according to one or more embodiments. FIGS. 2 to 4 are enlarged diagrams illustrating examples of region A of FIG. 1 according to one or more embodiments.

Referring to FIGS. 1 and 2, the semiconductor package may include a package substrate 10 for mounting a semiconductor chip, an external device or an external substrate.

The package substrate 10 may be provided. The package substrate 10 may include a core portion 110, a lower buildup portion 120 disposed on a lower surface of the core portion 110, and an upper buildup portion 130 disposed on an upper surface of the core portion 110.

The core portion 110 may extend in one direction. The core portion 110 may include one core pattern on a plane. For example, the core portion 110 may have a plate shape. The core portion 110 is described as having the one core pattern, but embodiments are not limited thereto. According to one or more embodiments, the core portion 110 may include two or more core patterns. That is, the package substrate 10 may include a plurality of core patterns spaced apart from each other on a plane. An upper surface 110t and a lower surface 110b of the core portion 110 may each have a large surface roughness. This will be described in detail with the lower buildup portion 120 and the upper buildup portion 130. A hardness of a material that constitutes the core portion 110 may be greater than a hardness of a material that constitutes a lower insulating pattern 122 to be described later and a hardness of a material that constitutes an upper insulating pattern 132 to be described later. The core portion 110 may include an insulating material. For example, the core portion 110 may include glass. That is, the package substrate 10 may be a line substrate based on glass.

The core portion 110 may include vertical connection terminals 112 vertically penetrating the core portion 110. The vertical connection terminals 112 may extend from the lower surface 110b of the core portion 110 toward the upper surface 110t of the core portion 110. That is, the vertical connection terminals 112 may be core vias for vertically electrically connecting in the core portion 110. The vertical connection terminals 112 may be exposed on the lower surface 110b of the core portion 110, or on the upper surface 110t of the core portion 110. The vertical connection terminals 112 may electrically connect the upper buildup portion 130 and the lower buildup portion 120 which are described later. As illustrated in FIG. 2, the vertical connection terminals 112 may have a sandglass shape in which a central portion of the vertical connection terminals 112 is concave. For example, a width of the vertical connection terminals 112 may become larger from the central portion of the vertical connection terminals 112 toward an upper surface 112t of the vertical connection terminals 112 and a lower surface 112b of the vertical connection terminals 112, but embodiments are not limited thereto. The vertical connection terminals 112 may have a columnar shape in which the width thereof is constant regardless of a vertical level. The vertical connection terminals 112 may include a metal material such as copper (Cu) or tungsten (W).

The lower buildup portion 120 may cover the lower surface 110b of the core portion 110. The lower buildup portion 120 may contact the lower surface 110b of the core portion 110. Side surfaces of the lower buildup portion 120 may be aligned with side surfaces of the core portion 110. A width of the lower buildup portion 120 may be the same as a width of the core portion 110. The lower buildup portion 120 may include at least one first substrate line layer that may be sequentially stacked on the lower surface 110b of the core portion 110. Each of the first substrate line layers may include the lower insulating pattern 122 and a lower wiring pattern 124 in the lower insulating pattern 122. The lower wiring pattern 124 of any one first substrate line layer may be electrically connected to the lower wiring pattern 124 of another adjacent first substrate line layer. Hereinafter, based on the one first substrate line layer, the lower insulating pattern 122 and the lower wiring pattern 124 will be described in more detail.

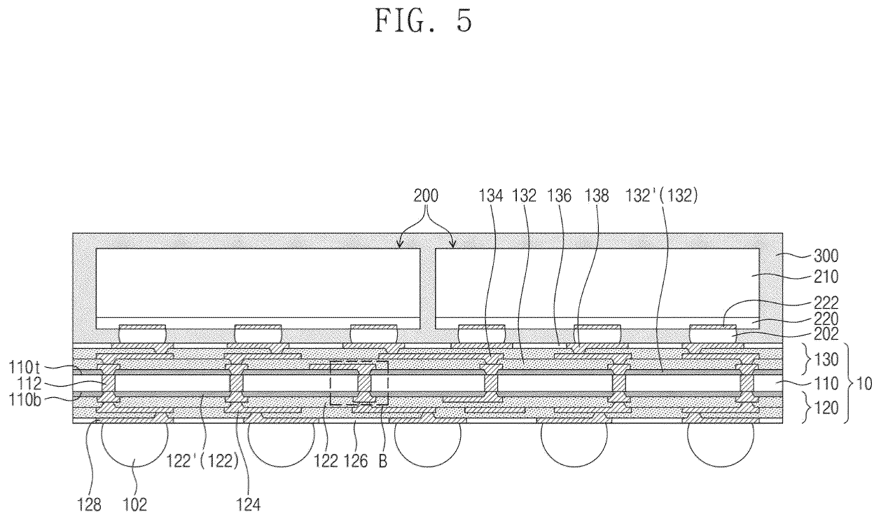

The hardness of the material that constitutes the lower insulating pattern 122 may be smaller than the hardness of the material that constitutes the core portion 110. The lower insulating pattern 122 may include prepreg, an aginomoto buildup film (ABF), FR-4, or bismaleimide triazine (BT). When the lower insulating pattern 122 includes the ABF, the lower insulating pattern 122 may include pillars dispersed in the lower insulating pattern 122. This will be described later in more detail with reference to FIGS. 5 to 8. On the other hand, the lower insulating pattern 122 may include an insulating polymer or a photosensitive insulating film (PID).

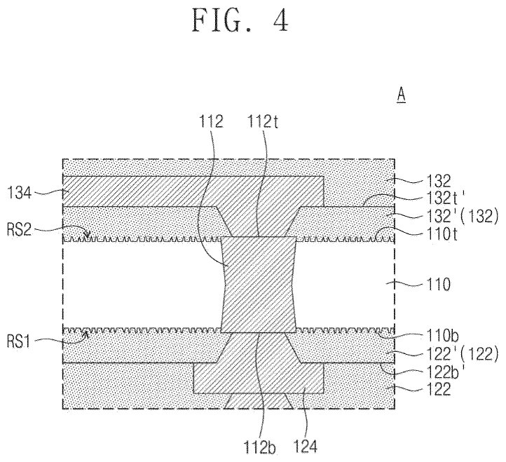

The lower insulating pattern 122 of the first substrate line layer disposed on the uppermost end of the first substrate line layers may contact the lower surface 110b of the core portion 110. Hereinafter, for convenience of description, the lower insulating pattern 122, of the uppermost first substrate line layer contacting the lower surface 110b of the core portion 110 will be referred to as a contact lower insulating pattern 122′. The surface roughness of the lower surface 110b of the core portion 110 may be larger than a surface roughness of a lower surface 122b′ of the contact lower insulating pattern 122′. For example, the lower surface 122b′ of the contact lower insulating pattern 122′ may be substantially flat. The lower surface 110b of the core portion 110 may include a plurality of first recesses RS1. The first recesses RS1 may have a concave shape toward an inner side of the core portion 110. The first recesses RS1 may be provided on the entire surface of the lower surface 110b of the core portion 110. That is, the first recesses RS1 may constitute irregularities formed on the entire surface of the lower surface 110b of the core portion 110. As illustrated in FIG. 2, cross-sections of the first recesses RS1 may each have a shape of a triangle of which a width becomes smaller toward the inside of the core portion 110. On the other hand, as illustrated in FIG. 3, the cross-sections of the first recesses RS1 may each have a concave or circular shape toward the inside of the core portion 110. Alternatively, as illustrated in FIG. 4, the cross-sections of the first recesses RS1 may each have a shape of a tetragon or a trapezoid of which a width becomes smaller toward the inside of the core portion 110. The lower surface 110b of the core portion 110 may have protrusions protruding from the lower surface 110b. The lower surface 110b of the core portion 110 may include the first recesses RS1 each having a trigonal cross-section described with reference to FIG. 2, the first recesses RS1 each having a circular shape described with reference to FIG. 3, or the first recesses RS1 each having a tetragonal cross-section described with reference to FIG. 4. That is, shapes of the first recesses RS1 formed on the lower surface 110b of the core portion 110 may be irregular. As the first recesses RS1 are provided on the lower surface 110b of the core portion 110, the lower surface 110b of the core portion 110 may have a large surface roughness. For example, the widths and depths, of the first recesses RS1, which are sizes of the first recesses RS1 may be about 0.1 μm to about 10 μm.

The surface roughness of the lower surface 110b of the core portion 110 may be larger than a surface roughness of the lower surface 112b of the vertical connection terminals 112.

The lower wiring patterns 124 may each include a circuit pattern or a wiring pattern. The lower wiring patterns 124 may be provided on the lower insulating pattern 122. The lower wiring patterns 124 may be provided on a lower surface of the lower insulating pattern 122. The lower wiring patterns 124 may protrude into the lower surface of the lower insulating pattern 122. The lower wiring patterns 124 may horizontally extend on the lower surface of the lower insulating pattern 122. The lower wiring patterns 124 may be covered by another lower insulating pattern 122 disposed under the lower insulating pattern 122. The lower wiring patterns 124 may be pad portions or line portions of the first substrate line layers. The lower wiring patterns 124 may each include a conductive material. For example, the lower wiring patterns 124 may each include one of copper (Cu), aluminum (Al), silver (Ag), tin (Sn), gold (Au), nickel (Ni), lead (Pb), titanium (Ti), or a combination thereof.

The lower wiring patterns 124 may each have a damascene structure. For example, the lower wiring patterns 124 may each have a via protruding onto an upper surface thereof. The via may be a configuration for vertically connecting the lower wiring patterns 124 of the first substrate line layers adjacent to each other. For example, the via may extend from the upper surface of the lower wiring pattern 124, and may penetrate the lower insulating pattern 122 to be connected to a lower surface of the lower wiring pattern 124 of another first substrate line layer placed thereon. In a case of the uppermost first substrate line layer, the via of the lower wiring pattern 124 may penetrate the contact lower insulating pattern 122′ to be connected to the lower surface 112b of the vertical connection terminals 112 of the core portion 110. That is, a lower portion of the lower wiring pattern 124 placed under the lower insulating pattern 122 may be a head portion used as a horizontal line or pad, and the via of the lower wiring pattern 124 may be a tail portion. The lower wiring pattern 124 may have an inverted T shape.

Lower substrate pads 128 may be provided on a lower surface of the lower buildup portion 120. The lower substrate pads 128 may vertically penetrate the lower insulating pattern 122 of the lowermost first substrate line layer to be connected to the lower wiring pattern 124. The lower substrate pads 128 may be provided as a portion of the lower wiring patterns 124 provided at the lowermost end, or as a separate pad.

A lower substrate protective film 126 may be provided under the lower buildup portion 120. The lower substrate protective film 126 may cover the lowermost first substrate line layer. The lower substrate protective film 126 may surround the lower substrate pads 128 on the lower surface of the lowermost first substrate line layer. The lower substrate pads 128 may be exposed on the lower surface of the lower substrate protective film 126. The lower substrate protective film 126 may include prepreg, an ABF, FR-4, or BT. The lower substrate protective film 126 may not be provided as needed.

External terminals 102 may be provided on the lower surface of the lower substrate pads 128. The external terminals 102 may include a solder ball or solder bump. The semiconductor package may be provided in a form of a ball grid array (BGA), a fine ball grid array (FBGA), or a land grid array (LGA) according to a type and a disposition of the external terminals 102.

The upper buildup portion 130 may cover the upper surface 110t of the core portion 110. The upper buildup portion 130 may contact the upper surface 110t of the core portion 110. Side surfaces of the upper buildup portion 130 may be aligned with side surfaces of the core portion 110. A width of the upper buildup portion 130 may be the same as the width of the core portion 110. The upper buildup portion 130 may include at least one second substrate line layer that may be sequentially stacked on the upper surface 110t of the core portion 110. Each of the second substrate line layers may include an upper insulating pattern 132 and an upper wiring pattern 134 in the upper insulating pattern 132. The upper wiring pattern 134 of any one second substrate line layer may be electrically connected to the upper wiring pattern 134 of another adjacent second substrate line layer. Hereinafter, based on the one second substrate line layer, the upper insulating pattern 132 and the upper wiring pattern 134 will be described in more detail.

A hardness of a material that constitutes the upper insulating pattern 132 may be smaller than a hardness of a material that constitutes the core portion 110. The upper insulating pattern 132 may include prepreg, an ABF, FR-4, or BT. When the upper insulating pattern 132 includes the ABF, the upper insulating pattern 132 may include pillars dispersed in the upper insulating pattern 132. This will be described later in more detail with reference to FIGS. 5 to 8. On the other hand, the upper insulating pattern 132 may include an insulating polymer or a PID.

The upper insulating pattern 132 of the second substrate line layer disposed on the lowermost end of the second substrate line layers may contact the upper surface 110t of the core portion 110. Hereinafter, for convenience of description, the upper insulating pattern 132 of the lowermost second substrate line layer contacting the upper surface 110t of the core portion 110 will be referred to as a contact upper insulating pattern 132′. The surface roughness of the upper surface 110t of the core portion 110 may be larger than the surface roughness of an upper surface 132t′ of the contact upper insulating pattern 132′. For example, the upper surface 132t′ of the contact upper insulating pattern 132′ may be substantially flat. The upper surface 110t of the core portion 110 may include a plurality of second recesses RS2. The second recesses RS2 may have a concave shape toward an inner side of the core portion 110. The second recesses RS2 may be provided on the entire surface of the upper surface 110t of the core portion 110. That is, the second recesses RS2 may constitute irregularities formed on the entire surface of the upper surface 110t of the core portion 110. As illustrated in FIG. 2, cross-sections of the second recesses RS2 may each have a shape of a triangle of which a width becomes smaller toward the inside of the core portion 110. On the other hand, as illustrated in FIG. 3, the cross-sections of the second recesses RS2 may each have a concave or circular shape toward the inside of the core portion 110. Alternatively, as illustrated in FIG. 4, the cross-sections of the second recesses RS2 may each have a shape of a tetragon or a trapezoid of which a width becomes smaller toward the inside of the core portion 110. The upper surface 110t of the core portion 110 may have protrusions protruding from the upper surface 110t. The upper surface 110t of the core portion 110 may include the second recesses RS2 each having a trigonal cross-section described with reference to FIG. 2, the second recesses RS2 each having a circular shape described with reference to FIG. 3, or the second recesses RS2 each having a tetragonal cross-section described with reference to FIG. 4. That is, shapes of the second recesses RS2 formed on the upper surface 110t of the core portion 110 may be irregular. As the second recesses RS2 are provided on the upper surface 110t of the core portion 110, the upper surface 110t of the core portion 110 may have a large surface roughness. For example, the widths and depths of the second recesses RS2, which are sizes of the second recesses RS2 may be about 0.1 μm to about 10 μm.

The surface roughness of the upper surface 110t of the core portion 110 may be greater than a surface roughness of the upper surface 112t of the vertical connection terminals 112.

The upper wiring patterns 134 may include a circuit pattern or a wiring pattern. The upper wiring patterns 134 may be provided on the upper insulating pattern 132. The upper wiring patterns 134 may be provided on an upper surface of the upper insulating pattern 132. The upper wiring patterns 134 may protrude into the upper surface of the upper insulating pattern 132. The upper wiring patterns 134 may horizontally extend on the upper surface of the upper insulating pattern 132. The upper wiring patterns 134 may be covered by another upper insulating pattern 132 disposed on the upper insulating pattern 132. The upper wiring pattern 134 may be a pad portion or a line portion of the second substrate line layer. The upper wiring patterns 134 may each include a conductive material. For example, the upper wiring pattern 134 may include one of copper (Cu), aluminum (Al), silver (Ag), tin (Sn), gold (Au), nickel (Ni), lead (Pb), titanium (Ti), or a combination thereof.

The upper wiring patterns 134 may each have a damascene structure. For example, the upper wiring patterns 134 may each have a via protruding into a lower surface thereof. The via may be a configuration for vertically connecting the upper wiring patterns 134 of the second substrate line layer adjacent to each other. For example, the via may extend from the lower surface of the upper wiring pattern 134, and may penetrate the upper insulating pattern 132 to be connected to an upper surface of the upper wiring pattern 134 of another second substrate line layer placed thereunder. In a case of the lowermost second substrate line layer, the via of the upper wiring pattern 134 may penetrate the contact upper insulating pattern 132′ to be connected to the upper surface 112t of the vertical connection terminal 112 of the core portion 110. That is, an upper portion of the upper wiring pattern 134 placed on the upper insulating pattern 132 may be a head portion used as a horizontal line or pad, and the via of the upper wiring pattern 134 may be a tail portion. The upper wiring patterns 134 may each have an inverted T shape.

Upper substrate pads 138 may be provided on an upper surface of the upper buildup portion 130. The upper substrate pads 138 may vertically penetrate the upper insulating pattern 132 of the uppermost second substrate line layer to be connected to the upper wiring pattern 134. The upper substrate pad 138 may be provided as a portion of the upper wiring pattern 134 provided at the uppermost end, or as a separate pad.

An upper substrate protective film 136 may be provided on the upper buildup portion 130. The upper substrate protective film 136 may cover the uppermost second substrate line layer. The upper substrate protective film 136 may surround the upper substrate pads 138 on the upper surface of the uppermost second substrate line layer. The upper substrate pads 138 may be exposed on the upper surface of the upper substrate protective film 136. The upper substrate protective film 136 may include prepreg, an ABF, FR-4, or BT. The upper substrate protective film 136 may not be provided as needed.

According to one or more embodiments, the core portion 110 of the package substrate 10 of the semiconductor package may provide the upper surface 110t and the lower surface 110b with the first and second recesses RS1 and RS2. Accordingly, the upper surface 110t and the lower surface 110b of the core portion 110 may each have a large surface roughness, and a large surface area. The upper surface 110t of the core portion 110 may have a large contact area with the contact upper insulating pattern 132′, and the lower surface 110b of the core portion 110 may have a large contact area with the contact lower insulating pattern 122′. Accordingly, an adhesive strength between the contact upper insulating pattern 132′ and the upper surface 110t of the core portion 110, and an adhesive strength between the contact lower insulating pattern 122′ and the lower surface 110b of the core portion 110 may be increased. That is, the core portion 110 and the lower buildup portion 120, and the core portion 110 and the upper buildup portion 130 may be firmly adhered, and the package substrate 10 with improved structural stability and the semiconductor package including the same may be provided.

Referring to FIG. 1, at least one semiconductor chip 200 may be provided on the package substrate 10. FIG. 1 illustrates that the semiconductor package includes two semiconductor chips 200, but embodiments are not limited thereto. The semiconductor chips 200 may each include a chip base layer 210 and a chip line layer 220.

The chip base layer 210 may include a semiconductor substrate. For example, the chip base layer 210 may be the semiconductor substrate such as a semiconductor wafer. An integrated circuit may be provided on a lower surface of the chip base layer 210. The integrated circuit may include a logic circuit or a memory circuit. That is, the semiconductor chip 200 may be a logic chip or memory chip. The lower surface of the semiconductor chip 200 may be an active surface, and the upper surface of the semiconductor chip 200 may be an inactive surface. That is, the semiconductor chip 200 may be disposed on the package substrate 10 in a face-down form.

The chip line layer 220 may be disposed on the lower surface of the chip base layer 210. For example, the chip line layer 220 may include a chip insulating pattern and a chip wiring pattern formed on the lower surface of the chip base layer 210. The chip insulating pattern may cover the integrated circuit on the lower surface of the chip base layer 210. The chip wiring pattern may be provided in the chip insulating pattern. The chip wiring pattern may be electrically connected to the integrated circuit formed on the lower surface of the chip base layer 210. A portion of the chip wiring pattern exposed on the lower surface of the chip line layer 220 may be chip pads 222 of the semiconductor chip 200. The chip line layer 220 may further include a circuit pattern or protective film, as needed.

The semiconductor chips 200 may be mounted on the package substrate 10. For example, the semiconductor chips 200 may be mounted on the package substrate 10 in a flip chip method. More specifically, the semiconductor chips 200 may be electrically connected to the package substrate 10 through connection terminals 202. The connection terminals 202 may be provided between the chip pads 222 of the semiconductor chips 200 and the upper substrate pads 138 of the package substrate 10. The semiconductor chips 200 may be electrically connected, through the connection terminals 202, to the upper buildup portion 130, the core portion 110, the lower buildup portion 120, and the external terminals 102 of the package substrate 10.

A molding film 300 may be disposed on the upper surface of the package substrate 10. The molding film 300 may cover the semiconductor chips 200. The molding film 300 may include an insulating polymer material. For example, the molding film 300 may include an epoxy molding compound (EMC).

Configurations to be described in embodiments below are described using the same reference numerals or symbols as those described in embodiments of FIGS. 1 to 4, and for convenience of description, repeated description thereof may be omitted. That is, differences between embodiments below and those of FIGS. 1 to 4 will be mainly described.

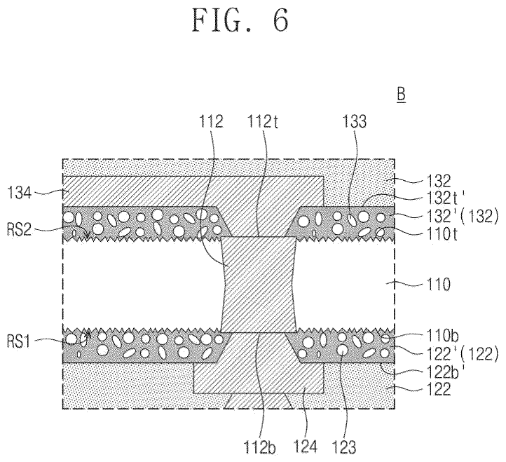

FIG. 5 is a cross-sectional view illustrating a semiconductor package according to one or more embodiments. FIG. 6 is an enlarged diagram illustrating region B of FIG. 5 according to one or more embodiments.

Referring to FIGS. 5 and 6, a lower buildup portion 120 may include at least one first substrate line layer and may be sequentially stacked on a lower surface 110b of a core portion 110. Each of the first substrate line layers may include a lower insulating pattern 122 and a lower wiring pattern 124 in the lower insulating pattern 122.

A contact lower insulating pattern 122′ of the first substrate line layer disposed on the uppermost end of the first substrate line layers may contact the lower surface 110b of the core portion 110. The contact lower insulating pattern 122′ may include a different material from the rest of the lower insulating patterns 122. For example, the contact lower insulating pattern 122′ may include an ABF. The contact lower insulating pattern 122′ may include first pillars 123 dispersed in the contact lower insulating pattern 122′. The first pillars 123 may each have a spherical or ellipsoidal shape. The rest of the lower insulating patterns 122 may each include an insulating polymer or a PID.

The lower surface 110b of the core portion 110 may have a larger surface roughness than the lower surface 122b′ of the contact lower insulating pattern 122′. For example, the lower surface 122b′ of the contact lower insulating pattern 122′ may be substantially flat. The lower surface 110b of the core portion 110 may include a plurality of first recesses RS1. Widths and depths of the first recesses RS1 may be smaller than diameters of the first pillars 123. For example, the widths and the depths of the first recesses RS1 may be about 0.1 μm to about 10 μm. The diameters of the first pillars 123 may be about 0.5 μm to about 6 μm.

An upper buildup portion 130 may include at least one second substrate line layer and may be sequentially stacked on the upper surface 110t of the core portion 110. Each of the second substrate line layers may include an upper insulating pattern 132 and an upper wiring pattern 134 in the upper insulating pattern 132.

A contact upper insulating pattern 132′ of the second substrate line layer disposed on the lowermost end of the second substrate line layers may contact the upper surface 110t of the core portion 110. The contact upper insulating pattern 132′ may include a different material from the rest of the upper insulating patterns 132. For example, the contact upper insulating pattern 132′ may include an ABF. The contact upper insulating pattern 132′ may include second pillars 133 dispersed in the contact upper insulating pattern 132′. The second pillars 133 may each have a spherical or ellipsoidal shape. The rest of the upper insulating patterns 132 may each include an insulating polymer or a PID.

The upper surface 110t of the core portion 110 may have a larger surface roughness than the upper surface 132t′ of the contact upper insulating pattern 132′. For example, the upper surface 132t′ of the contact upper insulating pattern 132′ may be substantially flat. The upper surface 110t of the core portion 110 may include a plurality of second recesses RS2. Widths and depths of the second recesses RS2 may be smaller than diameters of the second pillars 133. For example, the widths and the depths of the second recesses RS2 may be about 0.1 μm to about 10 μm. The diameters of the second pillars 133 may be about 0.5 μm to about 6 μm.

According to one or more embodiments, since the upper surface 110t and the lower surface 110b of the core portion 110 may each have a large roughness, a contact area between the first and second pillars 123 and 133 and the upper surface 110t and the lower surface 110b of the core portion 110 may be smaller, compared to a case in which the upper surface 110t and the lower surface 110b of the core portion 110 are flat. In addition, widths and depths of the first and second recesses RS1 and RS2 may be smaller than diameters of the first and second pillars 123 and 133. Accordingly, the first and second pillars 123 and 133 may not be inserted into the first and second recesses RS1 and RS2, and the contact area between the first and second pillars 123 and 133 and the upper surface 110t and the lower surface 110b of the core portion 110 may be minimized. Accordingly, although the contact lower insulating pattern 122′ and the contact upper insulating pattern 132′ have the first and second pillars 123 and 133, the contact areas between the upper surface 110t and the lower surface 110b of the core portion 110 and the contact lower insulating pattern 122′ and the contact upper insulating pattern 132′ may be large. Accordingly, an adhesive strength between the contact upper insulating pattern 132′ and the upper surface 110t of the core portion 110 and an adhesive strength between the contact lower insulating pattern 122′ and the lower surface 110b of the core portion 110 may be increased.

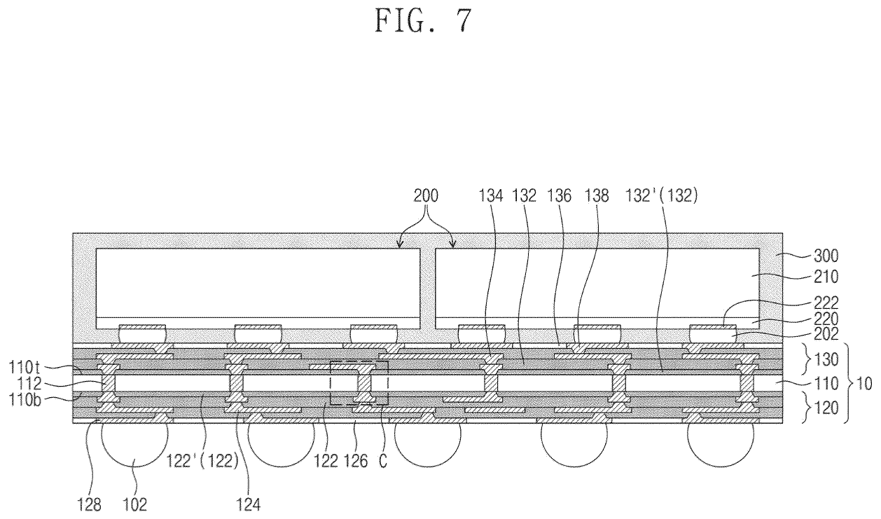

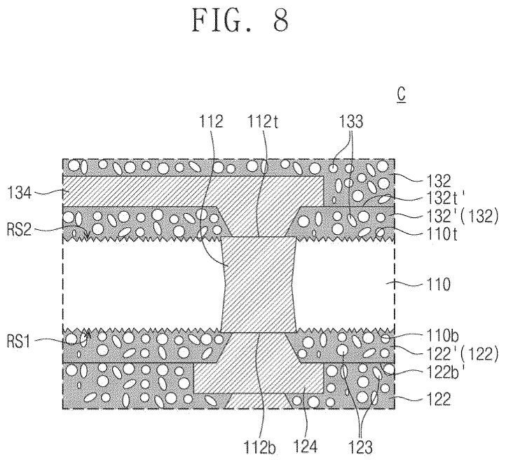

FIG. 7 is a cross-sectional view illustrating a semiconductor package according to one or more embodiments. FIG. 8 is an enlarged diagram illustrating region C of FIG. 7 according to one or more embodiments.

Referring to FIGS. 7 and 8, a lower buildup portion 120 may include at least one first substrate line layer and may be sequentially stacked on a lower surface 110b of a core portion 110. Each of the first substrate line layers may include a lower insulating pattern 122 and a lower wiring pattern 124 in the lower insulating pattern 122.

A contact lower insulating pattern 122′ of the first substrate line layer disposed on the uppermost end of the first substrate line layers may contact the lower surface 110b of the core portion 110. The contact lower insulating pattern 122′ may have the same material as the rest of the lower insulating patterns 122. For example, the contact lower insulating pattern 122′ and the rest of the lower insulating patterns 122 may include an ABF. The contact lower insulating pattern 122′ and the rest of the lower insulating patterns 122 may include first pillars 123 dispersed therein.

An upper buildup portion 130 may include at least one second substrate line layer and may be sequentially stacked on an upper surface 110t of the core portion 110. Each of the second substrate line layers may include an upper insulating pattern 132 and an upper wiring pattern 134 in the upper insulating pattern 132.

The contact upper insulating pattern 132′ of the second substrate line layer disposed on the lowermost end of the second substrate line layers may contact the upper surface 110t of the core portion 110. The contact upper insulating pattern 132′ may include the same material as the rest of the upper insulating patterns 132. For example, the contact upper insulating pattern 132′ and the rest of the upper insulating patterns 132 may include an ABF. The contact upper insulating pattern 132′ and the rest of the upper insulating patterns 132 may include second pillars 133 dispersed therein.

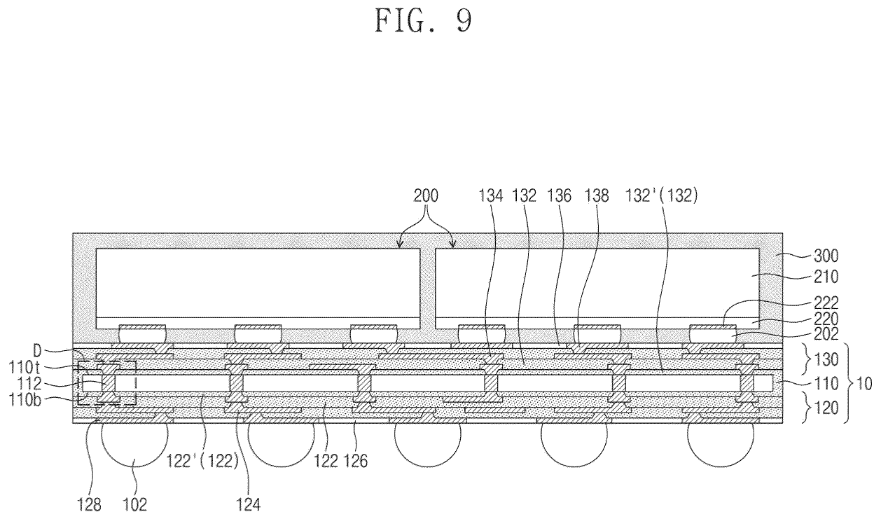

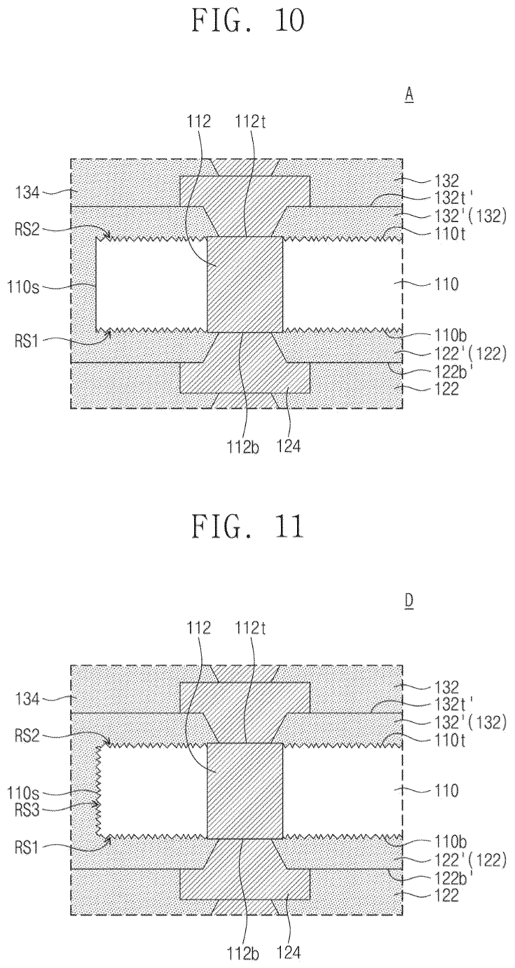

FIG. 9 is a cross-sectional view illustrating a semiconductor package according to one or more embodiments. FIGS. 10 and 11 are enlarged diagrams illustrating examples of region D of FIG. 9 according to one or more embodiments.

Referring to FIGS. 9 and 10, a lower buildup portion 120 may cover a lower surface 110b of a core portion 110. The lower buildup portion 120 may contact the lower surface 110b of the core portion 110. Side surfaces of the lower buildup portion 120 may be spaced apart from side surfaces 110s of the core portion 110. A width of the lower buildup portion 120 may be greater than a width of the core portion 110. The lower buildup portion 120 may entirely cover the lower surface 110b of the core portion 110. The core portion 110 may be inside the lower buildup portion 120 on a plane.

The lower buildup portion 120 may include at least one first substrate line layer and may be sequentially stacked on the lower surface 110b of the core portion 110. Each of the first substrate line layers may include a lower insulating pattern 122 and a lower wiring pattern 124 in the lower insulating pattern 122. A contact lower insulating pattern 122′ of the first substrate line layer disposed on the uppermost end of the first substrate line layers may contact the lower surface 110b of the core portion 110.

An upper buildup portion 130 may cover an upper surface 110t of the core portion 110. The upper buildup portion 130 may contact the upper surface 110t of the core portion 110. Side surfaces of the upper buildup portion 130 may be spaced apart from side surfaces 110s of the core portion 110. A width of the upper buildup portion 130 may be greater than a width of the core portion 110. The upper buildup portion 130 may entirely cover the upper surface 110t of the core portion 110. The core portion 110 may be inside the upper buildup portion 130 on a plane.

The upper buildup portion 130 may include at least one second substrate line layer and may be sequentially stacked on the upper surface 110t of the core portion 110. Each of the second substrate line layers may include an upper insulating pattern 132 and an upper wiring pattern 134 in the upper insulating pattern 132. A contact upper insulating pattern 132′ of the second substrate line layer disposed on the lowermost end of the second substrate line layers may contact the upper surface 110t of the core portion 110.

A contact lower insulating pattern 122′ may extend from the lower surface 110b of the core portion 110 onto the side surfaces 110s of the core portion 110. The contact upper insulating pattern 132′ may extend from the upper surface 110t of the core portion 110 onto the side surfaces 110s of the core portion 110. The contact lower insulating pattern 122′ and the contact upper insulating pattern 132′ may meet on the side surfaces 110s of the core portion 110. The contact lower insulating pattern 122′ and the contact upper insulating pattern 132′ may be integrally composed of the same material. For example, there may be no boundary surface between the contact lower insulating pattern 122′ and the contact upper insulating pattern 132′. The core portion 110 may be buried in one insulating pattern (122′ and 132′, hereinafter, referred to as a contact insulating pattern) composed of the contact lower insulating pattern 122′ and the contact upper insulating pattern 132′. However, embodiments are not limited thereto.

The contact insulating pattern 122′ and 132′ may contact the side surfaces 110s of the core portion 110. The side surfaces 110s of the core portion 110 may be substantially flat.

According to one or more embodiments, since the core portion 110 is buried in the contact insulating pattern 122′ and 132′, the core portion 110 may be protected from an external impact. In particular, the side surfaces 110s of the core portion 110 may not be exposed to the outside, and may be covered by the contact insulating pattern 122′ and 132′, and thus the core portion 110 may be protected from an impact from side surfaces of the package substrate 10.

According to one or more embodiments, as illustrated in FIG. 11, the side surfaces 110s of the core portion 110 may have a larger surface roughness than the upper surface 132t′ of the contact upper insulating pattern 132′ or the lower surface 122b′ of the contact lower insulating pattern 122′. For example, an upper surface 132t′ of the contact upper insulating pattern 132′ or the lower surface 122b′ of the contact lower insulating pattern 122′ may be substantially flat. The side surfaces 110s of the core portion 110 may have a plurality of third recesses RS3. The third recesses RS3 may have a concave shape toward the inside of the core portion 110. The third recesses RS3 may be on the entire side surfaces 110s of the core portion 110. That is, the third recesses RS3 may constitute irregularities formed on the entire side surfaces 110s of the core portion 110. The cross-sections of the third recesses RS3 may each have a shape of a triangle of which a width becomes smaller toward the inside of the core portion 110, a shape concave or circular toward the inside of the core portion 110, or a shape of a tetragon or a trapezoid of which a width becomes smaller toward the inside of the core portion 110. Since the third recesses RS3 are provided to the side surfaces 110s of the core portion 110, the side surfaces 110s of the core portion 110 may have a large surface roughness. For example, widths and depths of the third recesses RS3, which are sizes of the third recesses RS3, may be about 0.1 μm to about 10 μm.

According to one or more embodiments, the third recesses RS3 may be provided to the side surfaces 110s of the core portion 110 of the package substrate 10 of the semiconductor package. Accordingly, the side surfaces 110s of the core portion 110 may have a large surface roughness, and a large surface area. A contact area between the side surfaces 110s of the core portion 110 and the contact insulating pattern 122′ and 132′ may be large. Accordingly, an adhesive strength between the contact insulating pattern 122′ and 132′ and the side surfaces 110s of the core portion 110 may be increased. That is, the core portion 110 and the lower buildup portion 120 and the core portion 110 and the upper buildup portion 130 may be firmly adhered, and the package substrate 10 with improved structural stability and the semiconductor package including the same may be provided.

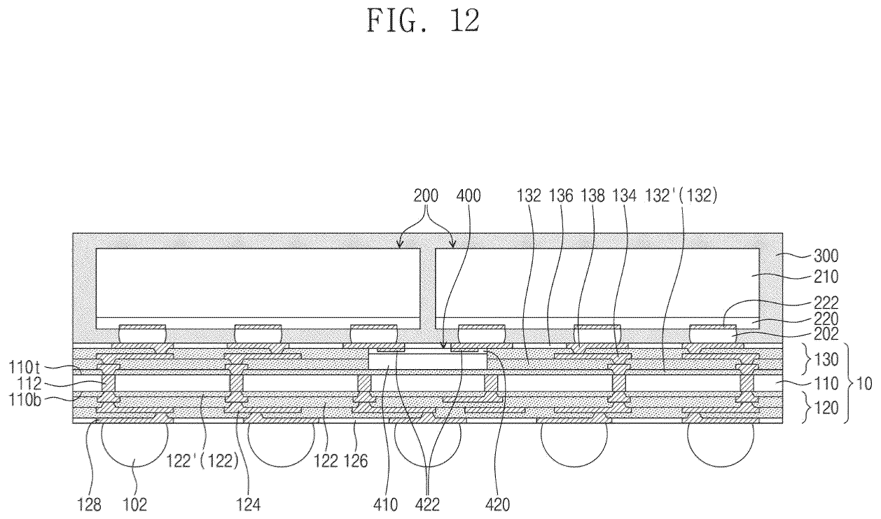

FIG. 12 is a cross-sectional view illustrating a semiconductor package according to one or more embodiments.

Referring to FIG. 12, a package substrate 10 of the semiconductor package may further include a bridge chip 400.

The bridge chip 400 may be disposed on the package substrate 10. The bridge chip 400 may be provided as a portion of the package substrate 10, but for convenience of description, the package substrate 10 and the bridge chip 400 will be described as separate configurations. The bridge chip 400 may be disposed on an upper surface 110t of the core portion 110. For example, the bridge chip 400 may contact the contact upper insulating pattern 132′ placed on the upper surface 110t of the core portion 110. The rest of upper insulating patterns 132 of the upper buildup portion 130 may completely surround the bridge chip 400 on the contact upper insulating pattern 132′, but embodiments are not limited thereto. The bridge chip 400 may contact the upper surface 110t of the core portion 110, and the contact upper insulating pattern 132′ and the rest of the upper insulating patterns 132 of the upper buildup portion 130 may completely surround the bridge chip 400 on the core portion 110.

The bridge chip 400 may have a front surface and a rear surface. Hereinafter, the front surface may be defined as a surface on which an active surface or lines of an integrated element in a semiconductor chip is/are formed, and pads of the semiconductor chip are formed, and the rear surface may be defined as an opposite surface of the front surface. The rear surface of the bridge chip 400 may face the core portion 110. That is, the bridge chip 400 may be disposed in a face-up form. The bridge chip 400 may be attached to the contact upper insulating pattern 132′ or the core portion 110 by using an adhesive layer. Vertical connection terminals 112 of the core portion 110 may not be provided under the bridge chip 400. The bridge chip 400 may include a bridge base layer 410 and a bridge line layer 420.

The bridge base layer 410 may include a semiconductor substrate. For example, the bridge base layer 410 may be a semiconductor substrate such as a semiconductor wafer. The bridge base layer 410 may be a silicon (Si) substrate, a silicon-on-insulator (SOI) substrate, a germanium (Ge) substrate, a germanium-on-insulator (GOI) substrate, a silicon-germanium (SiGe) substrate, a group 3-5 semiconductor substrate, or an epitaxial thin-film substrate obtained by performing a selective epitaxial growth (SEG). For example, the bridge base layer 410 may include at least one of silicon (Si), germanium (Ge), silicon-germanium (SiGe), gallium arsenide (GaAs), indium-gallium arsenide (InGaAs), aluminum-gallium arsenide (AlGaAs), and a mixture thereof.

The bridge line layer 420 may be disposed on an upper surface of the bridge base layer 410. For example, the bridge line layer 420 may include an insulating pattern and a wiring pattern formed on the upper surface of the bridge base layer 410. The bridge insulating pattern may include an insulating material. The bridge wiring pattern may be provided in the bridge insulating pattern. The bridge wiring pattern may be a configuration for electrically connecting the semiconductor chips 200. The bridge wiring pattern may include a conductive material. The bridge line layer 420 may further include a circuit pattern or a protective film as needed.

The bridge chip 400 may include bridge pads 422 provided on the upper surface of the bridge chip 400. The bridge pads 422 may be disposed on the upper surface of the bridge line layer 420. The bridge pads 422 may be exposed on the upper surface of the bridge line layer 420. Each of the bridge pads 422 may be disposed adjacent to any one of the semiconductor chips 200.

Upper substrate pads 138 may be provided on the upper surface of the upper buildup portion 130. The upper substrate pads 138 may be connected to the upper wiring pattern 134 of the uppermost second substrate line layer, or may be connected to the bridge pads 422 of the bridge chip 400.

An upper substrate protective film 136 may be provided on the upper buildup portion 130. The upper substrate protective film 136 may cover the uppermost second substrate line layer and the bridge chip 400. The upper substrate protective film 136 may surround the upper substrate pads 138 on the upper surface of the uppermost second substrate line layer.

The bridge chip 400 may be electrically connected to the semiconductor chips 200 through the upper substrate pads 138. The semiconductor chips 200 may be electrically connected to each other through the upper substrate pads 138 and the bridge chip 400.

FIG. 12 illustrates that the upper substrate protective film 136 and the upper substrate pads 138 are provided on the bridge chip 400, but embodiments are not limited thereto. According to one or more embodiments, the upper substrate protective film 136 may surround the bridge chip 400 on the upper insulating patterns 132, and the semiconductor chips 200 may be directly mounted on the bridge pads 422 of the bridge chip 400.

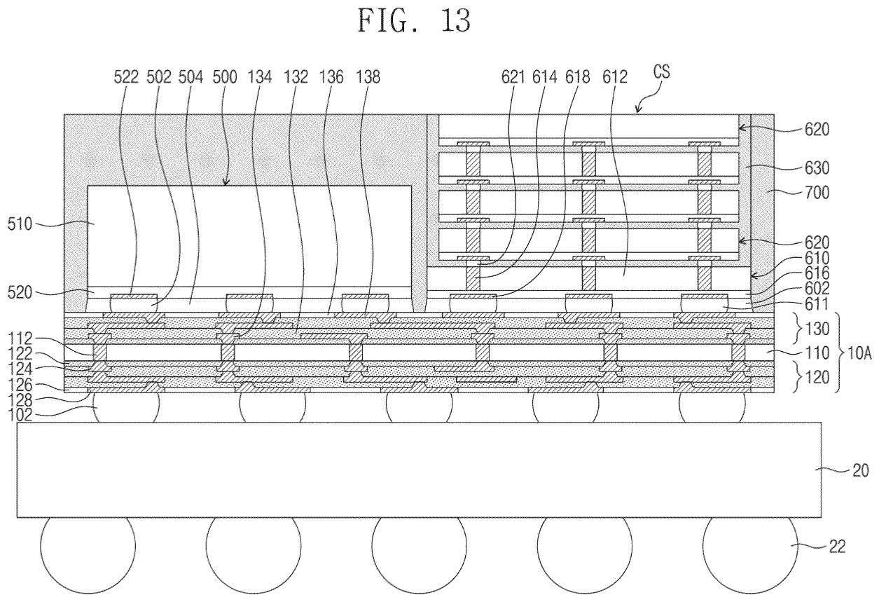

FIG. 13 is a cross-sectional view illustrating a semiconductor package according to one or more embodiments.

Referring to FIG. 13, the semiconductor package may be a semiconductor module. For example, the semiconductor module may be a memory module including a module substrate 20, a graphic processing unit 500 and a chip stack CS mounted on the module substrate 20, and a second molding film 700 covering the graphic processing unit 500 and the chip stack CS. The semiconductor module may further include an interposer 10A provided on the module substrate 20.

The module substrate 20 may be provided. The module substrate 20 may include a printed circuit board (PCB) having a signal pattern on an upper surface thereof.

Module terminals 22 may be disposed under the module substrate 20. The module terminals 22 may include a solder ball or solder bump, and the semiconductor module may be provided in a form of a BGA, a FBGA, or a LGA according to a type and a disposition of the module terminals 22. According to one or more embodiments, the module terminals 22 may not be provided.

The interposer 10A may be provided on the module substrate 20. The interposer 10A may have a similar structure to or the same structure as the package substrate 10 described with reference to FIGS. 1 to 12. For example, the interposer 10A may have a core portion 110, a lower buildup portion 120, and an upper buildup portion 130, and recesses may be provided on an upper surface and a lower surface of the core portion 110. That is, the upper surface and the lower surface of the core portion 110 may have a larger roughness than a surface of the upper insulating pattern 132 of the upper buildup portion 130 or a surface of the lower insulating pattern 122 of the lower buildup portion 120.

The interposer 10A may reline the graphic processing unit 500 and the chip stack CS. The interposer 10A may be mounted on the module substrate 20 in a flip-chip method. For example, the interposer 10A may be mounted on the module substrate 20 by using external terminals 102 provided on the lower substrate pads 128. A first underfill film may be provided between the module substrate 20 and the interposer 10A.

The graphical processing unit (GPU) 500 may be disposed on the interposer 10A. 500 may include the GPU or may be other processors, such as central processing units (CPUs), etc., as will be understood by one of ordinary skill in the art from the description herein. The GPU 500 may include a logic circuit. That is, the GPU 500 may be a logic chip. The GPU 500 may have a first circuit layer 520 provided on a lower surface of the GPU 500. The first circuit layer 520 may include integrated circuits (for example, the logic circuit) formed on one surface of a first semiconductor substrate 510, and lines electrically connected to the integrated circuits. First chip pads 522 may be provided on a lower surface of the GPU 500 (that is, a lower surface of the first circuit layer 520).

The GPU 500 may be mounted on the interposer 10A. For example, the first chip pads 522, and the upper substrate pads 138 of the interposer 10A may be connected to each other through first bumps 502 provided therebetween. A second underfill film 504 may be provided between the interposer 10A and the GPU 500. The second underfill film 504 may fill a space between the interposer 10A and the GPU 500, and may surround the first bumps 502.

The chip stack CS may be disposed on the interposer 10A. The chip stack CS may be spaced apart from the GPU 500. The GPU 500 may have a greater thickness than semiconductor chips 610 and 620 of the chip stack CS. An upper surface of the chip stack CS may be placed at the same level as or a higher level than an upper surface of the GPU 500.

The chip stack CS may include a base substrate, second semiconductor chips 620 stacked on the base substrate, and a first molding film 630 surrounding the second semiconductor chips 620. Hereinafter, configuration of the chip stack CS will be described in detail.

The base substrate may be a first semiconductor chip 610. For example, the base substrate may be a semiconductor substrate, which is a wafer made of a semiconductor material such as silicon (Si). Hereinafter, the first semiconductor chip 610 is referred to as the same component as the base substrate, and may use the same reference numerals or symbols as the base semiconductor chip and the base substrate.

The first semiconductor chip 610 may include a memory circuit. That is, the first semiconductor chip 610 may be a memory chip such as dynamic random access memory (RAM) (DRAM), static RAM (SRAM), magnetoresistive RAM (MRAM), flash memory, etc. The first semiconductor chip 610 may have a second circuit layer 616 provided on a lower surface of the first semiconductor chip 610. The second circuit layer 616 may include integrated circuits (for example, the logic circuit) formed on one surface of a second semiconductor substrate 612 and lines electrically connected to the integrated circuits. The first semiconductor chip 610 may include first penetration electrodes 614 vertically penetrating the second semiconductor substrate 612 to be connected to the second circuit layer 616. Second chip pads 618 may be provided on a lower surface of the first semiconductor chip 610, that is, a lower surface of the second circuit layer 616. According to one or more embodiments, the base substrate may be a line substrate not including the first semiconductor chip 610.

The second semiconductor chip 620 may include a memory circuit. That is, the second semiconductor chip 620 may be a memory chip such as DRAM, SRAM, MRAM, flash memory, etc. The second semiconductor chip 620 may include the same circuit as the first semiconductor chips 610, but embodiments are not limited thereto. The second semiconductor chip 620 may have a third circuit layer 626 provided on a lower surface of the second semiconductor chip 620. The third circuit layer 626 may include integrated circuits (for example, the logic circuit) formed on one surface of a third semiconductor substrate 622 and lines electrically connected to the integrated circuits. The second semiconductor chip 620 may include second penetration electrodes 624 vertically penetrating the third semiconductor substrate 622 to be connected to the third circuit layer 626. Third chip pads 628 may be provided on a lower surface of the second semiconductor chip 620 (that is, a lower surface of the third circuit layer 626).

The second semiconductor chip 620 may be mounted on the first semiconductor chip 610. The second semiconductor chip 620 may have a smaller width than the first semiconductor chip 610. Second bumps 621 may be provided on the third chip pads 628 of the second semiconductor chip 620, and the second bumps 621 may be connected to upper surfaces of first penetration electrodes 614 exposed on an upper surface of the first semiconductor chip 610. Alternatively, the third chip pads 628 of the second semiconductor chip 620 may directly contact the upper surfaces of the first penetration electrodes 614. That is, the second semiconductor chip 620 may have a chip-on-wafer (COW) structure with the first semiconductor chip 610.

A plurality of second semiconductor chips 620 may be provided. For example, a plurality of second semiconductor chips 620 may be stacked on the first semiconductor chip 610. 8 to 32 of the second semiconductor chips 620 may be stacked. In this case, the second semiconductor chip 620 disposed on the uppermost end thereof may not include the second penetration electrodes 624. In addition, the second semiconductor chip 620 disposed on the uppermost end thereof may have a greater thickness than the second semiconductor chips 620 disposed thereunder.

The second semiconductor chips 620 adjacent to each other may be adhered to each other. For example, the second bumps 621 may be provided on the third chip pads 628 of the second semiconductor chip 620, and may be connected to upper surfaces of the second penetration electrodes 624 exposed on an upper surface of the second semiconductor chip 620 disposed thereunder. Alternatively, the third chip pads 628 of the second semiconductor chips 620 may directly contact the upper surfaces of the second penetration electrodes 624 of the second semiconductor chip 620 placed thereunder.

A first molding film 630 may be disposed on an upper surface of the first semiconductor chip 610. The first molding film 630 may cover the first semiconductor chip 610, and may surround the second semiconductor chips 620. An upper surface of the first molding film 630 may be coplanar with an upper surface of the uppermost second semiconductor chip 620, and the uppermost second semiconductor chip 620 may be exposed from the first molding film 630. The first molding film 630 may include an insulating polymer material. For example, the first molding film 630 may include an EMC.

The chip stack CS may be mounted on the interposer 10A. For example, the second chip pads 618 and the upper substrate pads 138 of the interposer 10A may be connected to each other through a third bumps 611 provided therebetween. A third underfill film 602 may be provided between the interposer 10A and the chip stack CS. The third underfill film 602 may fill a space between the interposer 10A and the chip stack CS, and may surround the third bumps 611.

The second molding film 700 may be provided on the interposer 10A. The second molding film 700 may cover an upper surface of the interposer 10A. The second molding film 700 may surround the GPU 500 and the chip stack CS. An upper surface of the second molding film 700 may be placed at the same level as the upper surface of the chip stack CS. The second molding film 700 may include an insulating material. For example, the second molding film 700 may include an EMC.

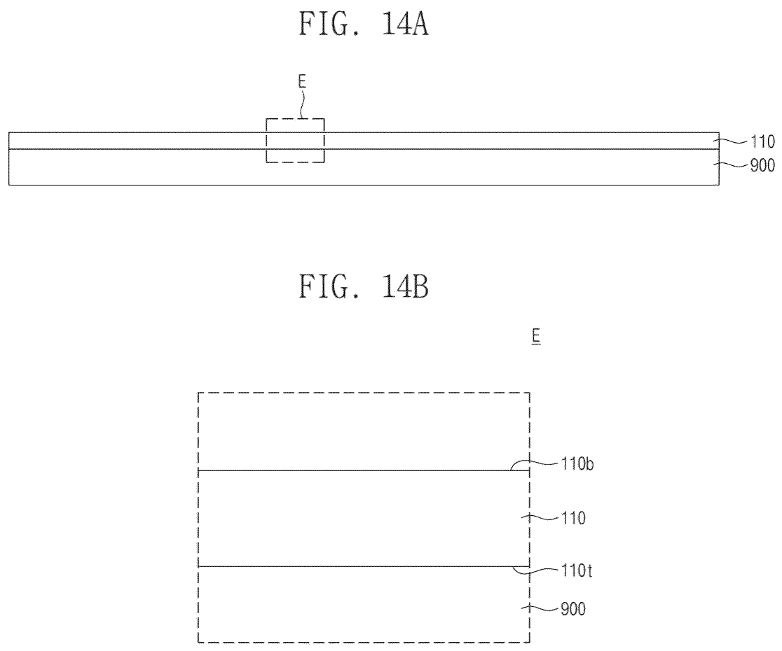

FIGS. 14A to 20A are cross-sectional views illustrating a method for manufacturing a semiconductor package according to one or more embodiments. FIGS. 14B to 20B are enlarged diagrams respectively illustrating region E of FIGS. 14A to 20A according to one or more embodiments.

Referring to FIGS. 14A and 14B, a carrier substrate 900 may be provided. The carrier substrate 900 may be an insulating substrate including glass or polymer, or a conductive substrate including metal. An adhesive member may be provided on an upper surface of the carrier substrate 900. For example, the adhesive member may include an adhesive tape.

A core portion 110 may be attached on the carrier substrate 900. The core portion 110 may have a plate shape. The core portion 110 may include an insulating material. For example, the core portion 110 may include a glass fiber. That is, a package substrate 10 may be a glass-based line substrate. The core portion 110 may have a first surface 110t facing the carrier substrate 900 and a second surface 110b opposed to the first surface. The first surface 110t and the second surface 110b may correspond to the upper surface 110t and the lower surface 110b of the core portion 110 described with reference to FIGS. 1 to 11.

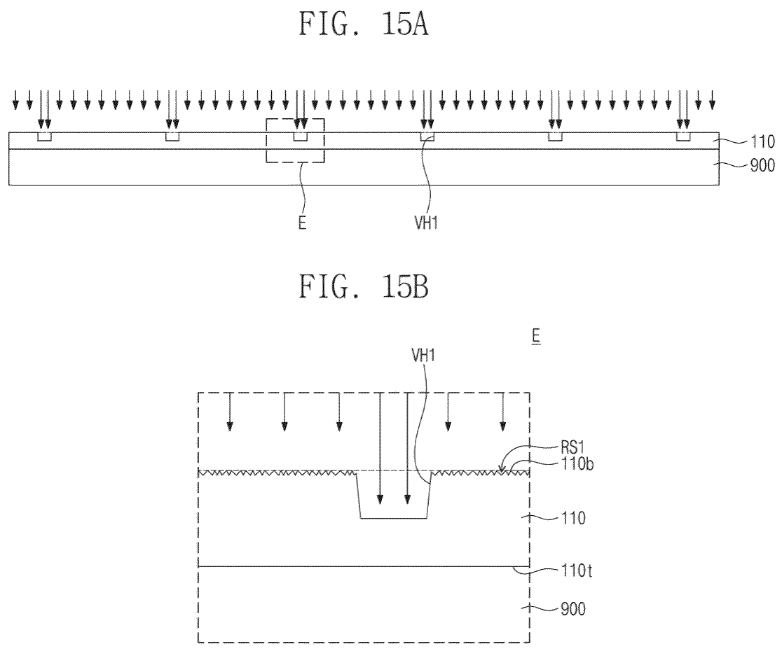

Referring to FIGS. 15A and 15B, a first etching process may be performed on the second surface 110b of the core portion 110. First via holes VH1 may be formed on the core portion 110 by the first etching process. The first etching process may be an etching process using laser. For example, the first etching process may include a laser-induced deep etch (LIDE) process. The first via holes VH1 may extend from the second surface 110b of the core portion 110 toward the inside of the core portion 110. A bottom surface of the first via holes VH1 may be spaced apart from the first surface 110t of the core portion 110. That is, the first via holes VH1 may not completely penetrate the core portion 110 vertically. Widths of the first via holes VH1 may become smaller in a direction getting farther from the second surface 110b of the core portion 110. The first via holes VH1 may be upper portions or lower portions of via holes for forming vertical connection terminals 112 in a process to be described later.

While the first etching process is performed, first recesses RS1 may be formed on the second surface 110b of the core portion 110. For example, during the first etching process, lasers having different intensities may be emitted on a region in which the first via holes VH1 are formed and the remaining region on the second surface 110b of the core portion 110. For example, the laser emitted onto the region in which the first via holes VH1 are formed may have a greater intensity than the laser emitted onto the remaining region of the second surface 110b of the core portion 110. That is, in the first etching process, an etch rate on the region in which the first via holes VH1 are formed may be greater than an etch rate on the remaining region of the second surface 110b. Since the first recesses RS1 are formed on the second surface 110b of the core portion 110, a surface roughness of the second surface 110b of the core portion 110 may be increased after the first etching process.

According to one or more embodiments, a process of forming the first via holes VH1 in the core portion 110 and a process of forming the first recesses RS1 on the second surface 110b of the core portion 110 may be simultaneously performed through the one first etching process. That is, the method for manufacturing a semiconductor package having fewer processes and being simple may be provided.

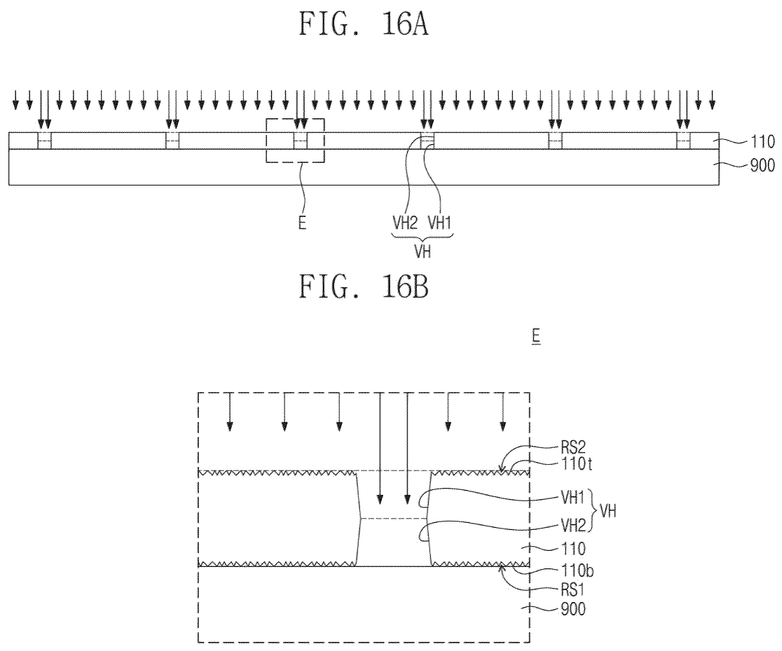

Referring to FIGS. 16A and 16B, the core portion 110 may be inverted on the carrier substrate 900. Accordingly, the second surface 110b of the core portion 110 may face the carrier substrate 900, and the first surface 110t of the core portion 110 may be opposed to the carrier substrate 900. FIGS. 16A and 16B illustrate that the carrier substrate 900 is the same as those of FIGS. 14A, 14B, 15A, and 15B, but embodiments are not limited thereto. According to one or more embodiments, another carrier substrate may be attached on the second surface 110b of the core portion 110, and then the carrier substrate that has been attached to the first surface 110t of the core portion 110 may be removed.

A second etching process may be performed on the first surface 110t of the core portion 110. Second via holes VH2 may be formed on the core portion 110 by the second etching process. The second etching process may be an etching process using laser. For example, the second etching process may include an LIDE process. The second via holes VH2 may extend from the first surface 110t of the core portion 110 toward the inside of the core portion 110. Widths of the second via holes VH2 may become smaller in a direction as they extend farther from the first surface 110t of the core portion 110. The second via holes VH2 may be vertically connected to the first via holes VH1. The first via holes VH1 and the second via holes VH2 may constitute via holes VH for forming the vertical connection terminals 112 in a process to be described later. The via holes VH may vertically completely penetrate the core portion 110.

While the second etching process is performed, second recesses RS2 may be formed on the first surface 110t of the core portion 110. For example, during the second etching process, lasers having different intensities may be emitted onto a region in which the second via holes VH2 are formed and the remaining region on the first surface 110t of the core portion 110. For example, the laser emitted onto the region in which the second via holes VH2 are formed may have a greater intensity than the laser emitted onto the remaining region of the first surface 110t of the core portion 110. That is, in the second etching process, an etch rate on the region in which the second via holes VH2 are formed may be greater than an etch rate on the remaining region of the first surface 110t. Since the second recesses RS2 are formed on the first surface 110t of the core portion 110, a surface roughness of the first surface 110t of the core portion 110 may be increased after the second etching process.

According to one or more embodiments, a process of forming the second via holes VH2 in the core portion 110 and a process of forming the second recesses RS2 on the first surface 110t of the core portion 110 may be simultaneously performed through the one second etching process. That is, the method for manufacturing a semiconductor package having fewer processes and being simple may be provided.

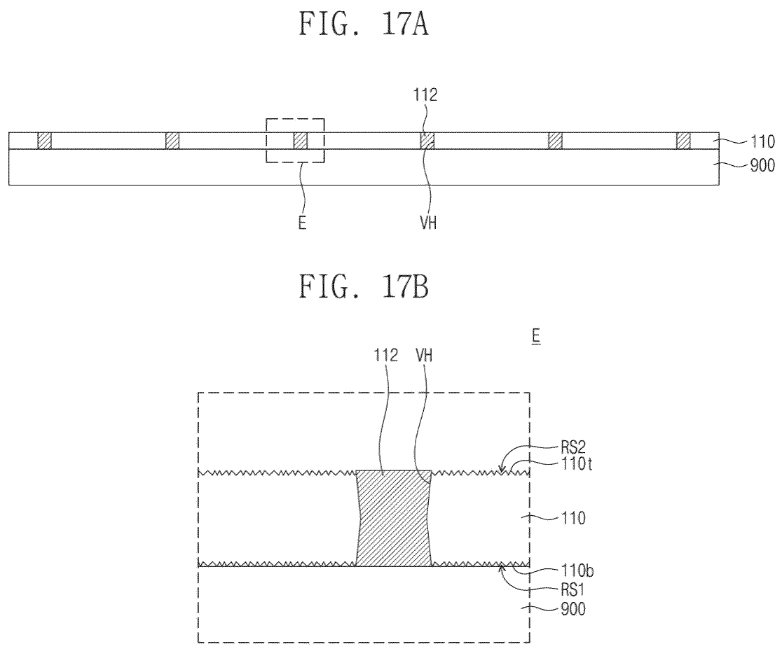

Referring to FIGS. 17A and 17B, the vertical connection terminals 112 may be formed by filling the via holes VH with a conductive material. For example, a process of forming the vertical connection terminals 112 may include a plating process. The vertical connection terminals 112 may include a metal material such as copper (Cu) or tungsten (W).

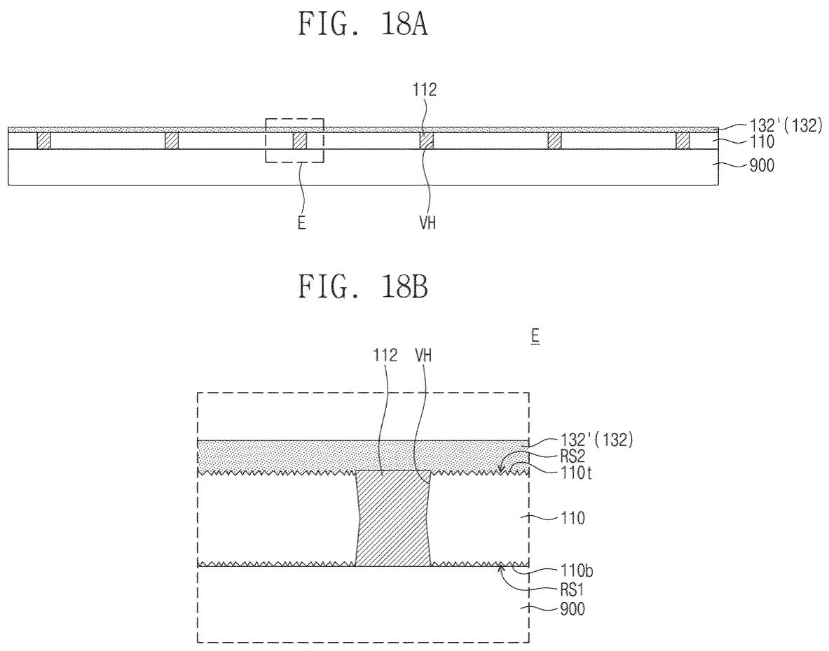

Referring to FIGS. 18A and 18B, a contact upper insulating pattern 132′ may be formed on the core portion 110. For example, the contact upper insulating pattern 132′ may be formed by applying an insulating material on the first surface 110t of the core portion 110 and upper surfaces of the vertical connection terminals 112. Alternatively, the contact upper insulating pattern 132′ may be directly attached on the first surface 110t of the core portion 110 and the upper surfaces of the vertical connection terminals 112. In this case, a compression process for adhering the contact upper insulating pattern 132′ on the first surface 110t of the core portion 110 may be additionally performed. The insulating material or the upper insulating pattern 132 may include prepreg, an ABF, FR-4, BT, an insulating polymer, or a PID.

According to one or more embodiments, since the core portion 110 of the package substrate 10 of the semiconductor package provides the second recesses RS2 to the first surface 110t, the first surface 110t of the core portion 110 may have a large contact area with the contact upper insulating pattern 132′. Accordingly, an adhesive strength between the contact upper insulating pattern 132′ and the first surface 110t of the core portion 110 may be increased, and a defect such as peeling of the contact upper insulating pattern 132′ may not occur.

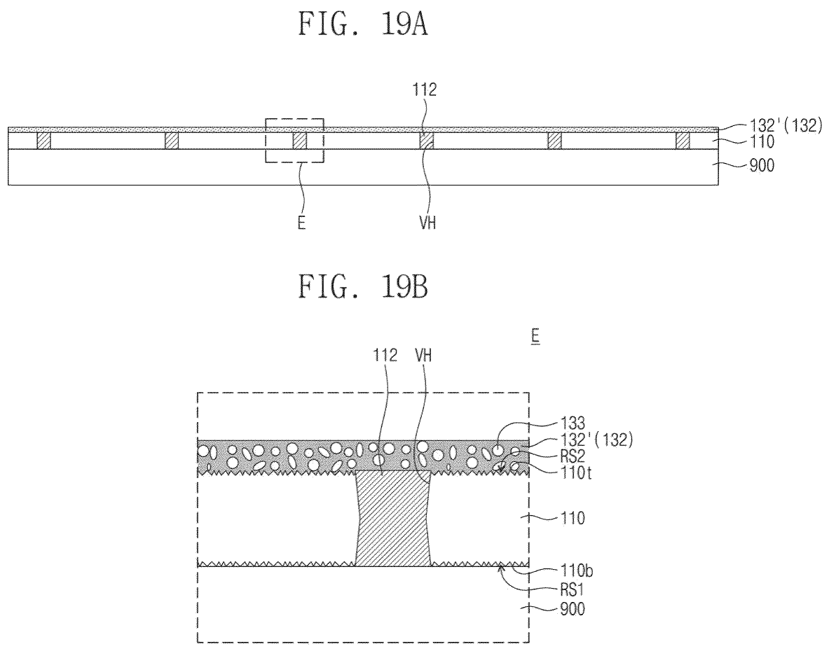

According to one or more embodiments, as illustrated in FIGS. 19A and 19B, the upper insulating pattern 132 may include second pillars 133 dispersed in the contact upper insulating pattern 132′. The contact upper insulating pattern 132′ may be formed on the core portion 110. For example, the contact upper insulating pattern 132′ may be formed by applying an insulating material onto the first surface 110t of the core portion 110 and the upper surfaces of the vertical connection terminals 112. In this case, a contact area between the second pillars 133 and the first surface 110t of the core portion 110 may be minimized by the second recesses RS2 formed on the first surface 110t.

Alternatively, the contact upper insulating pattern 132′ may be directly attached on the first surface 110t of the core portion 110 and the upper surfaces of the vertical connection terminals 112. In this case, a compression process for adhering the contact upper insulating pattern 132′ on the first surface 110t of the core portion 110 may be additionally performed. Widths and depths of the second recesses RS2 may be smaller than diameters of the second pillars 133. Accordingly, the second pillars 133 may not be inserted into the second recesses RS2 during the compression process, and a contact area between the second pillars 133 and the first surface 110t of the core portion 110 may be minimized.

According to one or more embodiments, since the contact area between the second pillars 133 and the first surface 110t of the core portion 110 is small, the first surface 110t of the core portion 110 may have a large contact area with the contact upper insulating pattern 132′. Accordingly, the contact upper insulating pattern 132′ has the second pillars 133, but an adhesive strength between the contact upper insulating pattern 132′ and the first surface 110t of the core portion 110 may be increased, and a defect such as peeling of the contact upper insulating pattern 132′ may not occur.

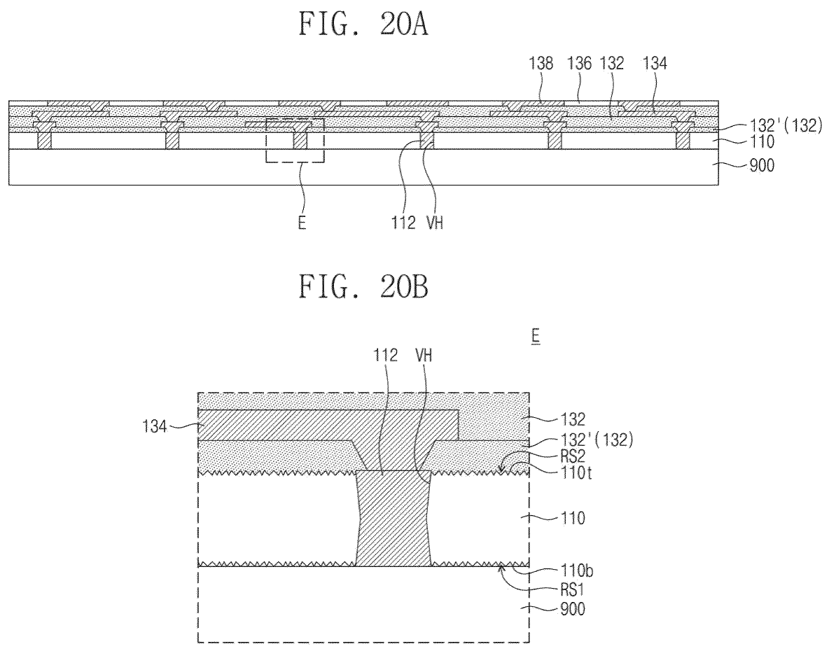

Referring to FIGS. 20A and 20B, the upper surface of the vertical connection terminals 112 may be exposed by patterning the contact upper insulating pattern 132′, and the upper wiring patterns 134 may be formed by forming a conductive layer covering the contact upper insulating pattern 132′ and patterning the conductive layer. One substrate line layer of the upper buildup portion 130 may be formed in this way. Thereafter, the upper buildup portion 130 may be formed by repeatedly performing processes of depositing and patterning an insulating layer and processes of depositing and patterning a conductive layer.

Upper substrate pads 138 may be formed on the uppermost line layer, and an upper substrate protective film 136 surrounding the same may be formed.

Thereafter, the carrier substrate 900 may be removed to expose the second surface 110b of the core portion 110. A lower buildup portion 120 may be formed on the second surface 110b of the core portion 110. A process of forming the lower buildup portion 120 may be substantially similar to or the same as the process of forming the upper buildup portion 130 described with reference to FIGS. 18A to 20A and 18B to 20B. For example, a lower surface of the vertical connection terminals 112 may be exposed by depositing or attaching the contact lower insulating pattern 122′ on the second surface 110b of the core portion 110, and patterning the contact lower insulating pattern 122′, and the lower wiring patterns 124 may be formed by forming a conductive layer on the lower surface of the contact lower insulating pattern 122′, and patterning the conductive layer. One substrate line layer of the lower buildup portion 120 may be formed in this way. Thereafter, the lower buildup portion 120 may be formed by repeatedly performing processes of depositing and patterning an insulating layer and processes of depositing and patterning a conductive layer. Lower substrate pads 128 may be formed on the lowermost line layer, and the lower substrate protective film 126 surrounding the same may be formed.

Referring back to FIG. 1, at least one semiconductor chip 200 may be mounted on the package substrate 10. A molding film 300 may be formed on the package substrate 10 so as to cover the at least one semiconductor chip 200 by applying and curing a molding member.

External terminals 102 may be attached on lower substrate pads 128 of the lower buildup portion 120.

A semiconductor package according to one or more embodiments may provide recesses to a surface of a core portion of a package substrate. Accordingly, the surface of the core portion may have a large surface roughness, and a large surface area. The surface of the core portion may have a large contact area with a contact insulating pattern. Accordingly, an adhesive strength between the contact insulating pattern and the surface of the core portion may be increased. That is, a lower buildup portion and the core portion, and an upper buildup portion and the core portion may be firmly adhered, and the package substrate with improved structural stability and the semiconductor package including the same may be provided.

In addition, widths and depths of the recesses formed on the surface of the core portion may be smaller than diameters of pillars dispersed in the contact insulating pattern. Accordingly, the pillars may not be inserted into the recesses, and a contact area between the pillars and the surface of the core portion may be minimized. Accordingly, the contact insulating pattern may have the pillars, but the surface of the core portion and the contact insulating pattern may have a large contact area. Accordingly, an adhesive strength between the contact insulating pattern and the surface of the core portion may be increased.

A method for manufacturing a semiconductor package according to one or more embodiments may simultaneously perform, through one etching process, a process of forming via holes in the core portion, and a process of forming the recesses on the surface of the core portion. That is, the method for manufacturing a semiconductor package having fewer processes and being simple may be provided.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a core portion comprising glass;
a vertical connection terminal penetrating the core portion;
an upper buildup portion at least partially covering an upper surface of the core portion; and
a lower buildup portion at least partially covering a lower surface of the core portion,
wherein the upper buildup portion comprises:
a first insulating pattern at least partially covering the upper surface of the core portion and an upper surface of the vertical connection terminal; and
a first wiring pattern penetrating the first insulating pattern and connected to the vertical connection terminal,
wherein the lower buildup portion comprises:
a second insulating pattern at least partially covering the lower surface of the core portion and a lower surface of the vertical connection terminal; and
a second wiring pattern penetrating the second insulating pattern and connected to the vertical connection terminal, and
wherein a surface roughness of the upper surface of the core portion and a surface roughness of the lower surface of the core portion are respectively larger than a surface roughness of an upper surface of the first insulating pattern and a surface roughness of a lower surface of the second insulating pattern.

2. The semiconductor package of claim 1, wherein the first insulating pattern comprises first pillars in the first insulating pattern, and
wherein the second insulating pattern comprises second pillars in the second insulating pattern.

3. The semiconductor package of claim 2, wherein the core portion comprises first recesses on the upper surface of the core portion, and second recesses on the lower surface of the core portion,
wherein widths and depths of the first recesses are smaller than diameters of the first pillars, and
wherein widths and depths of the second recesses are smaller than diameters of the second pillars.

4. The semiconductor package of claim 3, wherein the widths and the depths of the first recesses and the widths and the depths of the second recesses are in a range of 0.1 μm to 10 μm, and
wherein the diameters of the first pillars and the diameters of the second pillars are in a range of 0.5 μm to 6 μm.

5. The semiconductor package of claim 3, wherein each of the first recesses and the second recesses comprises a tetragon, a triangle, or a semi-circle shape in a cross-section.

6. The semiconductor package of claim 1, wherein the first insulating pattern directly contacts the upper surface of the core portion, and
wherein the second insulating pattern directly contacts the lower surface of the core portion.

7. The semiconductor package of claim 1, wherein the upper buildup portion further comprises third insulating patterns on the first insulating pattern,
wherein the lower buildup portion further comprises fourth insulating patterns on the second insulating pattern,
wherein the third insulating patterns comprise a material that is different from a material of the first insulating pattern, and
wherein the fourth insulating patterns comprise a material that is different form a material of the second insulating pattern.

8. The semiconductor package of claim 1, wherein the first insulating pattern and the second insulating pattern each comprise an aginomoto buildup film (ABF), a photosensitive insulating film, or an insulating polymer.

9. The semiconductor package of claim 1, wherein the first insulating pattern of the upper buildup portion and the second insulating pattern of the lower buildup portion cover side surfaces of the core portion.

10. The semiconductor package of claim 9, wherein a surface roughness of the side surfaces of the core portion is larger than the surface roughness of the upper surface of the first insulating pattern and the surface roughness of the lower surface of the second insulating pattern.

11. The semiconductor package of claim 1, further comprising a chip stack comprising:
a first semiconductor chip on the upper buildup portion; and
second semiconductor chips on the upper buildup portion and spaced apart from each other.

12. A semiconductor package comprising:
a package substrate; and
a semiconductor chip on the package substrate,
wherein the package substrate comprises:
a core portion comprising glass;
an upper buildup portion at least partially covering an upper surface of the core portion; and
a lower buildup portion at least partially covering a lower surface of the core portion,
wherein the upper buildup portion comprises:
a first upper insulating pattern contacting the upper surface the core portion; and
an upper wiring pattern on the first upper insulating pattern,
wherein the lower buildup portion comprises:
a first lower insulating pattern contacting the lower surface of the core portion; and
a lower wiring pattern on the first lower insulating pattern,
wherein the first upper insulating pattern and the first lower insulating pattern comprise pillars therein,
wherein the core portion comprises recesses on the upper surface and the lower surface of the core portion, and
wherein widths and depths of the recesses are smaller than diameters of the pillars.

13. The semiconductor package of claim 12, wherein the widths and the depths of the recesses are in a range of 0.1 μm to 10 μm, and
wherein the diameters of the pillars are in a range of 0.5 μm to 6 μm.

14. The semiconductor package of claim 12, wherein a surface roughness of the upper surface of the core portion and a surface roughness of the lower surface of the core portion are respectively larger than a surface roughness of one surface of the first upper insulating pattern and a surface roughness of one surface of the first lower insulating pattern.

15. The semiconductor package of claim 12, wherein the recesses comprise a tetragon, a triangle, or a semi-circle shape in a cross-section.

16. The semiconductor package of claim 12, wherein the first upper insulating pattern and the first lower insulating pattern cover a side surface of the core portion.

17. The semiconductor package of claim 16, wherein a surface roughness of the side surface of the core portion is larger than a surface roughness of one surface of the first upper insulating pattern and a surface roughness of one surface of the first lower insulating pattern.

18. The semiconductor package of claim 12, wherein the upper buildup portion further comprises second upper insulating patterns on the first upper insulating pattern,
wherein the lower buildup portion further comprises second lower insulating patterns on the first lower insulating pattern,
wherein the second upper insulating patterns comprise a material that is different from a material of the first upper insulating pattern, and
wherein the second lower insulating patterns comprise a material that is different form a material of the first lower insulating pattern.

19. A method of manufacturing a semiconductor package, the method comprising:
providing a core portion comprising glass;
forming a first hole extending from a first surface toward the inside of the core portion by performing a first etching process on the first surface of the core portion;
forming a via hole by forming a second hole extending from a second surface toward the inside of the core portion by performing a second etching process on the second surface of the core portion, the second surface of the core portion being opposite to the first surface of the core portion and the second hole being connected to the first hole;
forming a vertical connection terminal by filling the via hole with a conductive material;
forming a first insulating pattern contacting the first surface of the core portion;
forming a first wiring pattern penetrating the first insulating pattern and connected to the vertical connection terminal;
forming a second insulating pattern contacting the second surface of the core portion; and
forming a second wiring pattern penetrating the second insulating pattern and connected to the vertical connection terminal,
wherein, during the first etching process, the first surface of the core portion is etched together to increase a surface roughness of the first surface,
wherein, during the second etching process, the second surface of the core portion is etched together to increase a surface roughness of the second surface, and
wherein the first insulating pattern and the second insulating pattern comprise pillars therein.

20. The method of claim 19, wherein the first etching process and the second etching process each comprise a laser-induced deep etch (LIDE) process,
wherein, during the first etching process, a laser emitted to a region for forming the first hole on the first surface has a different intensity from a laser emitted to a remaining region of the first surface, and
wherein, during the second etching process, a laser emitted to a region for forming the second hole on the second surface has a different intensity from a laser emitted to a remaining region of the second surface.
